(19) United States
(12) Patent Application Publication
(10) Pub. No.: US 2009/0109720 A1
(43) Pub. Date: Apr. 30, 2009

(54) Memory Structure

(76) Inventor: Bohumil Lojek, Colorado Springs, CO (US)

Correspondence Address: FISH & RICHARDSON P.C., PO BOX 1022, MINNEAPOLIS, MN, 55440-1022, US

(21) Appl. No.: 11/924,514

(22) Filed: Oct. 25, 2007

(51) Int. Cl. G11C 5/02

(52) U.S. Cl. 365/51

(57) ABSTRACT

The subject matter of this specification can be embodied in, among other things, a method for manufacturing and a structure of a byte-addressable electrically erasable programmable read-only memory (EEPROM). In a first aspect, a byte-addressable EEPROM integrated circuit includes isolation means, in each of a plurality of memory bytes, for electrically isolating the EEPROM byte select transistor from an EEPROM memory bit disposed closest to the byte select transistor. In one example, the isolation means precludes the need to use a wide STI oxide for isolation, and thereby avoids the process variation of active area of memory bits.

### TECHNICAL FIELD

The subject matter of this patent application is generally related to non-volatile memory structures.

### BACKGROUND

Byte-addressable memory (e.g., an Electrically Erasable Programmable Read-Only Memory (EEPROM or E²PROM)) is typically organized as an array of individually-selectable memory bytes. In a byte-addressable EEPROM, the memory bytes are individually electrically programmable and erasable. Each of the EEPROM memory bytes typically includes eight floating-gate memory bits to store eight bits of data.

Cross-talk can cause errors in the values stored in the memory bits. Typically, during fabrication of a memory structure, isolation regions can be constructed to prevent electrical cross-talk between adjacent bits of memory, between memory transistors, bit select transistors and byte select transistors. One example isolation technique is shallow trench isolation (STI), using trenches filled with dielectric material, such as silicon dioxide.

In one example, the STI process involves using reactive-ion etching (RIE) to etch a pattern of shallow (e.g., ˜1 μm) trenches or grooves in a silicon substrate of the memory device. Each trench is then filled with a dielectric material, such as silicon dioxide. Excess dielectric is then removed using a technique such as chemical-mechanical planarization. For example, this process can be performed using a low pressure chemical vapor deposition (LPCVD) and a chemical mechanical polishing (CMP) to planarize the structure.

Narrow STI oxide regions disposed between two adjacent memory bits typically suffice to prevent cross-talk between the memory bits. Wider STI oxide regions are typically required to prevent cross-talk between a memory bit and active areas with elevated electrical potential, such as between a memory bit at the edge of a byte of memory and the byte select transistor for that byte. Active areas are areas of the substrate in which active structures, such as transistors or memory bits, are formed. To prevent cross-talk, the active areas are typically isolated from one another by insulating regions.

Process variation can compromise the effectiveness of STI oxide regions. For example, process variation introduces more significant variability in the width of the active area. For EEPROM memories fabricated with a large feature size, for example greater than 0.25 μm, the width of wide STI oxides can typically be adequately controlled even in spite of process variation. But as EEPROM memories become denser and feature sizes get smaller, for example 0.18 μm or smaller, process variation plays a larger role and the variation in the width of the wide STI oxides typically is not acceptable.

To address the problem of the variability of the width of the wide STI oxide, some EEPROM memories can optionally use dummy cells, instead of STI oxides, at the edge of each memory block. In some examples, these dummy cells can occupy a large portion (e.g., 1 bit for every memory byte or in excess of 3%, 5%, or 10%) of total memory area. Additionally, the contacts between the EEPROM bytes' word lines and the byte select transistor can occupy a similar amount of area (e.g., 1 bit for every memory byte). The area required by these dummy cells and the area required by the contacts can result in 10-bits of area being required for every 8-bits of memory, which can significantly increase the overall size and cost of the memory structure.

### SUMMARY

The subject matter of this specification can be embodied in, among other things, a method for manufacturing and a structure of a byte-addressable Electrically Erasable-Programmable Read-Only Memory (EEPROM). In a first aspect, a byte-addressable EEPROM integrated circuit includes isolation means, in each of a plurality of memory bytes, for electrically isolating the EEPROM byte select transistor from an EEPROM memory bit disposed closest to the byte select transistor. In one example, the isolation means precludes the need to use a wide STI oxide for isolation, and thereby avoids the process variation associated with the wide STI oxide.

Implementations can include any, all or none of the following features. In some implementations, the isolation means can be used to provide an additional function separate from the electrical isolation function. In some implementations, the byte-addressable EEPROM integrated circuit can include a contact pad for connecting an EEPROM word line to an EEPROM byte select gate that is disposed on the dummy bit area.

In a second aspect, a method of reducing the effect of process variations in an EEPROM can include modifying the mask pattern to create, in each memory byte of the EEPROM, a dummy bit area. The dummy bit area can be in each memory byte of the EEPROM. The dummy bit area can be disposed between the EEPROM byte select transistor and the EEPROM memory bit disposed closest to the byte select transistor. The dummy bit area can be substantially identical in size and orientation to each of the memory bits of the memory byte, and spaced apart from the memory bits by a width substantially identical to the width of the separation among the memory bits. The method further includes photolithographically exposing the silicon substrate to define the dummy bit area at the same time that the EEPROM memory bits are defined. The method further includes creating shallow trench isolation oxide regions on either side of the memory bits and the dummy bit. The dummy bit area can isolate the byte select transistor from the memory bit disposed closest to the byte select transistor, and precludes the need to use a wide STI oxide for isolation. Therefore, the dummy bit area can avoid the process variation associated with the wide STI oxide.

Implementations can include any, all or none of the following features. In some implementations, the method can include using the dummy bit area to provide an additional function separate from an electrical isolation function. In some implementations, the method can include a contact pad for connecting an EEPROM word line to an EEPROM byte select is disposed on the dummy bit area.

In a third aspect, a byte-addressable EEPROM integrated circuit includes a dummy bit area, in each of a plurality of memory bytes in the EEPROM, disposed between an EEPROM byte select transistor and an EEPROM memory bit disposed closest to the byte select transistor. The dummy bit area isolates the memory bit electrically from the byte select transistor. The dummy bit area precludes the need to use a wide STI oxide, thereby avoiding the greater process variation associated with the wide STI oxide.

Implementations can include any, all or none of the following features. In some implementations, the dummy bit area is used to provide an additional function separate from an electrical isolation function. In some implementations, the byte-addressable EEPROM integrated circuit can include a contact pad for connecting an EEPROM word line to an EEPROM byte select is disposed on the dummy bit area. In some implementations, the byte-addressable EEPROM integrated circuit can include N vertically directed columns of memory bytes comprising N/2 pairs of memory bytes that are substantially coplanar (lying in a substantially similar geometric plane) and symmetric about a Y-axis and are mirror-images of each other. In some implementations, the byte-addressable EEPROM integrated circuit can include M horizontally directed rows of memory bytes comprise M/2 pairs of memory bytes that are symmetric about a X-axis and are mirror-images of each other.

Implementations can provide any, all or none of the following advantages. For example, the size of the byte-addressable EEPROM integrated circuit can be reduced. For example, the byte-addressable EEPROM integrated circuit can provide a required electrical isolation within the circuit to prevent electrical cross-talk between semiconductor components.

### DESCRIPTION OF DRAWINGS

FIG. 1 shows an example circuit of a byte-addressable memory.

FIG. 2 shows an example memory structure having shallow trench isolation features and dummy regions.

FIGS. 3A-3C show multiple views of an example memory structure including a contact constructed to substantially align with a dummy region.

FIG. 4 shows an example process for reducing the effect of process variations in a non-volatile memory.

Like reference symbols in the various drawings indicate like elements.

### DETAILED DESCRIPTION

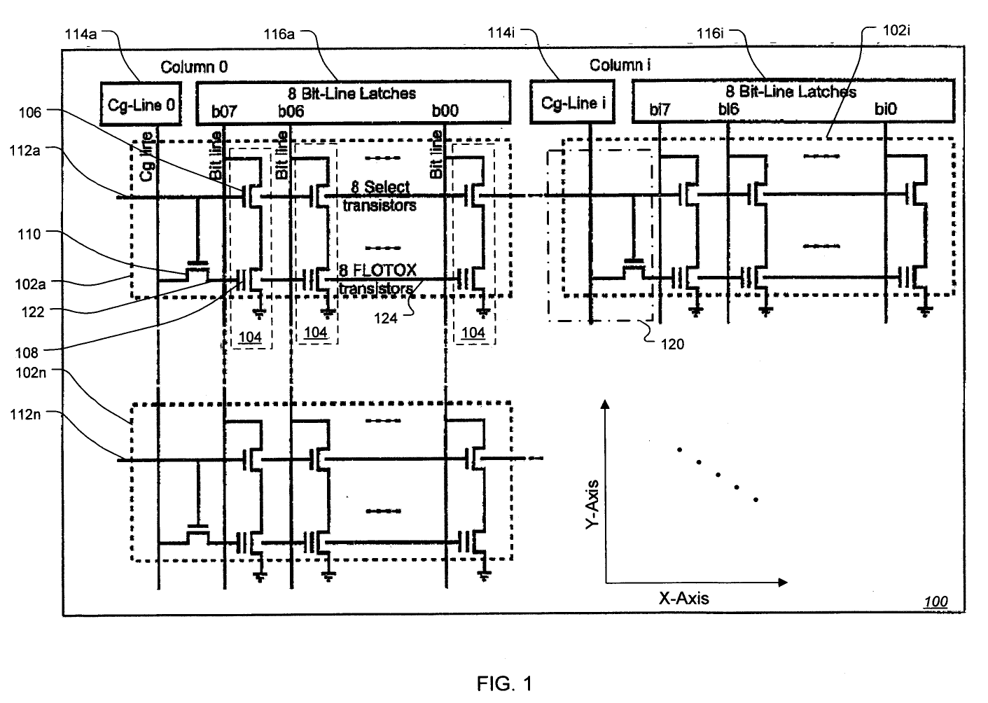

FIG. 1 shows an example circuit 100 of a byte-addressable memory (e.g., an EEPROM). As shown, the circuit 100 includes i+1 columns of memory arrays. Each memory array includes n+1 memory blocks 102. In this example, the memory blocks memory blocks 102a, 102i, 102n are shown. For example, the memory block 102a is the memory block located at column 0 and row 0, the memory block 102i is located at column i and row 0, and the memory block 102n is located at column 0 and row n. In this example, each of the memory blocks 102 can store one byte or eight bits of data. In some examples, depending on the specific design of a memory structures, the circuit 100 can include, for example, 16, 32, 64, or 128 memory blocks in a row. In some examples, the circuit 100 can also include 2, 4, 8, 16 rows of memory blocks.

Each of the memory blocks 102 includes eight memory cells 104 to store a byte of data. For example, each of the memory cells 104 can store one bit of data. In this example, each of the memory cells 104 includes a bit select transistor 106 and a Floating Gate Tunnel Oxide (FLOTOX) transistor 108. For example, the bit select transistor 106 can allow a voltage for programming a FLOTOX transistor 108 connected to the bit select transistor 106 based on a received control gate voltage. For example, the FLOTOX transistor 108 is a floating gate transistor that includes an oxide-nitride-oxide layer that stores charges representing a stored data. In some implementations, other floating gate transistors can also be used in the memory circuit 100. For example, EPROM tunnel oxide (ETOX™) transistors can also be used.

Each of the memory blocks 102 includes a byte select transistor 110. As shown, the byte select transistor 110 of a memory block 102 is connected in parallel with control gates of the FLOTOX transistors 108 in the same memory block 102 via a control gate 124.

The circuit 100 includes select gates 112a, . . . , 112n. Each of the select gates 112a-n is associated with one of the rows in the memory. In this example, each of the select gates 112a-n is connected in parallel with control gates of the select transistors 108 in the associated row.

For each column of the memory, the circuit 100 includes Cg-lines 114a-i and 8 bit-line latches 116a-i. As shown, each of the Cg-line 114a-i is commonly connected to source terminals of the byte select transistors 110 in a memory column. In one implementation, each of the 8 bit-line latches 116a-i supplies eight bit line voltages to one of the memory columns a-i. Each of the bit line voltage is supplied to memory cells 104 connected to a corresponding bit line. In the depicted example, each of the bit line voltages from the 8 bit-line latches 116a is associated with one of the 8 bits for the memory blocks 102 in the column 0. For example, the bit line b07 supplies a bit line voltage to bit 7 of the memory blocks in the column 0 (e.g., the memory blocks 102a, 102n). In another example, the bit line bi6 supplies a bit line voltage to bit 6 of the memory blocks in column i (e.g., the memory block 102i shown in FIG. 1). For example, each of the memory cells 104 of a memory block receives an independent bit line voltage via the bit select transistors 106.

In operation, one of the memory blocks 102 can be selected using the Cg-line 114 and the select gate 112a-n. Based on signals in the Cg-lines 114a-i and the select gate 112a-n, the byte select transistor 110 can enable a selected memory block. For example, the byte select transistor 110 can enable the memory block 102a if the select gate 112a and the Cg-line 116a carry the signals to enable the column 0 and the row 0. In one example, the byte select transistor 110 can enable the FLOTOX transistors 108 to be programmed by the bit line voltages. In one example, the bit line voltages can be passed to source terminals of the FLOTOX transistor 108 through the enabled bit select transistors 106.

In some implementations, the circuit 100 can be implemented in one or more semiconductor integrated circuits. In various examples, semiconductor integrated circuits include devices (e.g., the devices in the circuit 100) formed on a semiconductor body, such as a substrate. These devices, such as transistors, are formed in active areas in the semiconductor body. The active areas are typically isolated from one another by insulating regions. For example, the insulating region can electrically insulate the active areas from, for example, electrical cross-talking. In one implementation of a non-volatile memory, individual memory bits are disposed in the active area, and are isolated from each other by shallow trench isolation (STI) oxide. In some examples, the integrated circuits can include areas with different device patterns. For example, an area (e.g., an area 120) separating two bytes of memory cells may be a wide field area with lower density of devices. In some examples, electrical isolations between active bits in an memory integrated circuit can vary based on changes in device densities. In some implementations, the circuit 100 can include dummy cells in a lower density area (e.g., the area 120) to reduce process variation due to variations of trench slopes of isolation regions. In some examples, the dummy cells can reduce the byte separation area by including at least part of a contact region for connecting the byte select transistor 110 and the memory cells 104.

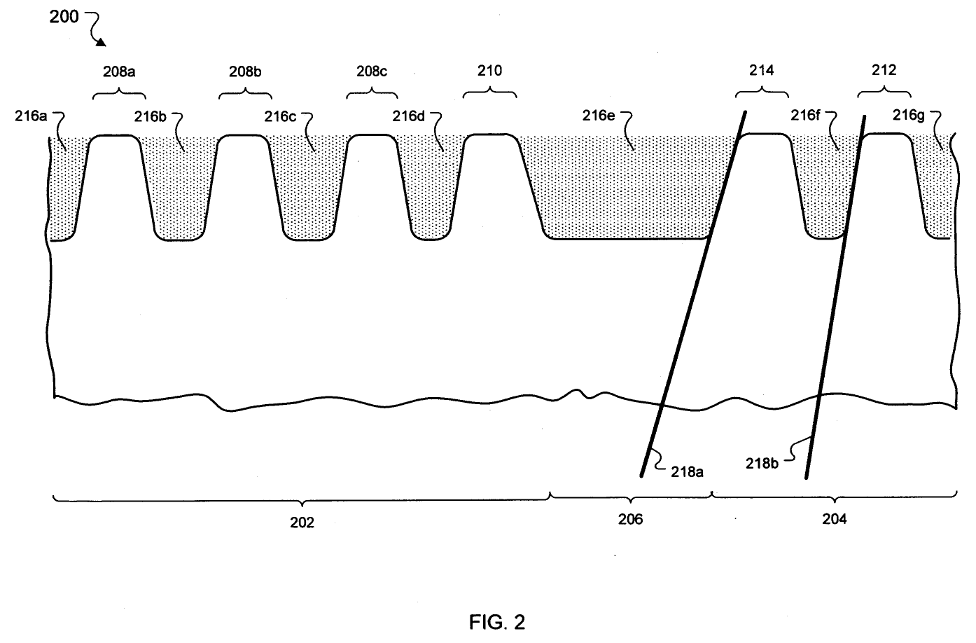

FIG. 2 shows an example partial view of a memory structure 200 having shallow trench isolation (STI) features and dummy regions. For example, the memory structure 200 can be included in a byte-addressable EEPROM memory as described with reference to FIG. 1.

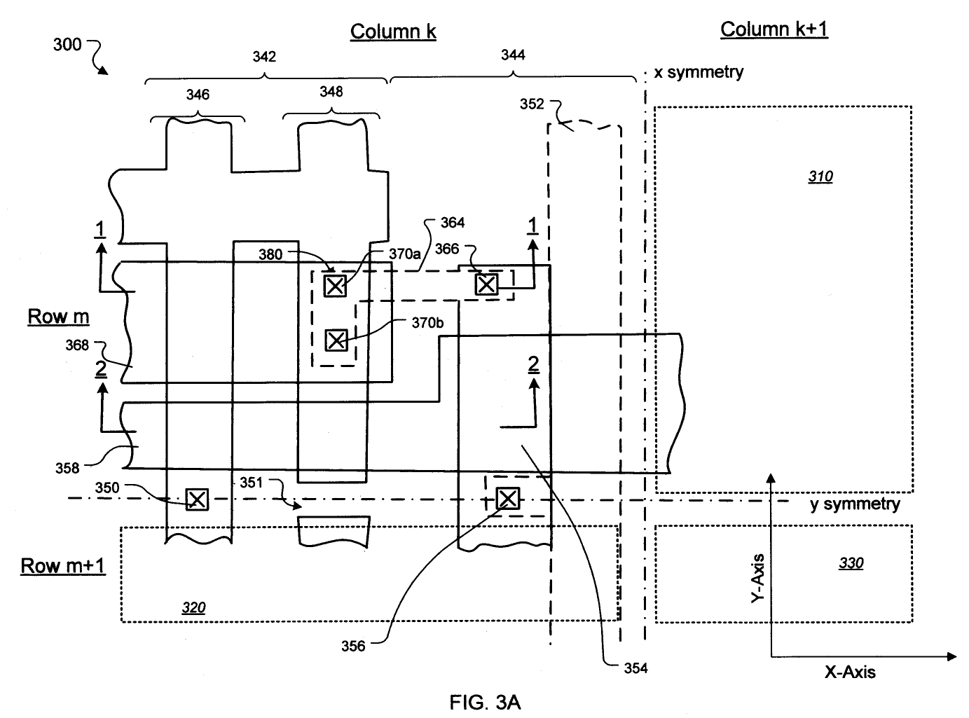

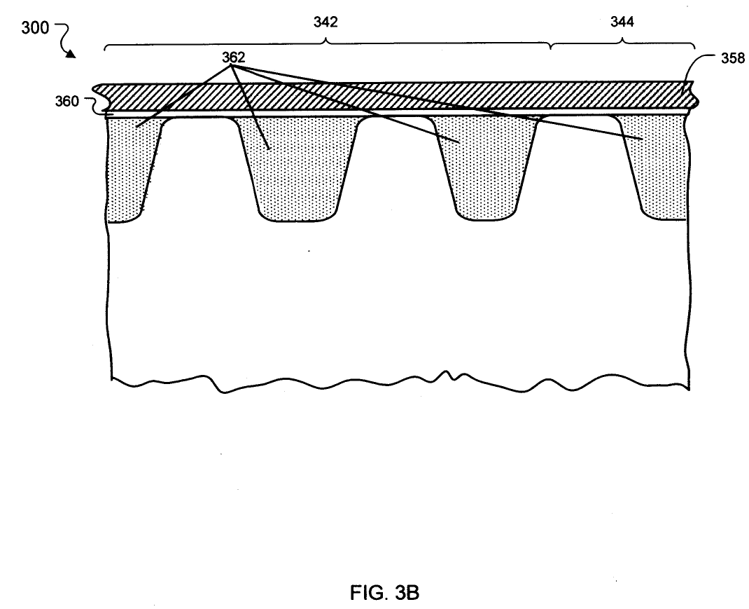

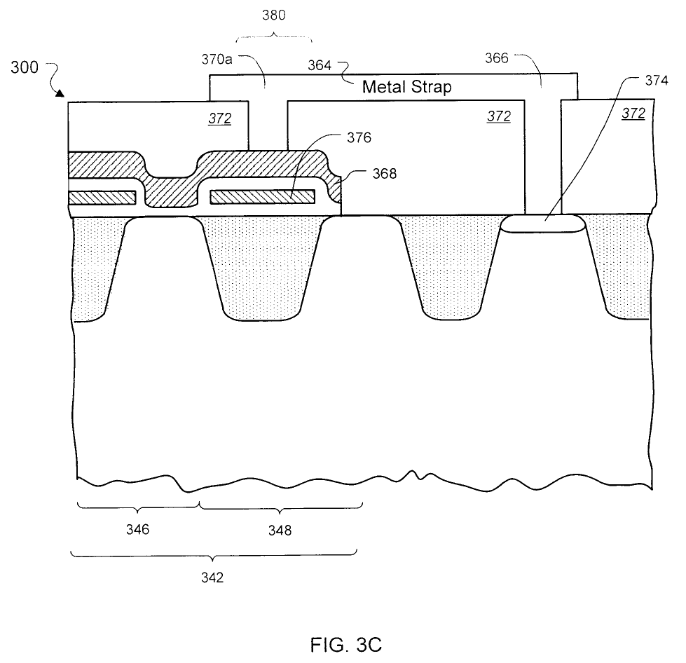

In the depicted example, the memory structures 200 include a part of a first memory byte region 202 and a part of a second memory byte region 204. For example, the memory byte regions 202, 204 may be two adjacent memory blocks. Between the memory byte regions 202, 204, the memory structure 200 includes a byte separation region 206. For example, the byte separation region 206 separates two adjacent memory bytes in an EEPROM. In some implementations, the byte separation region 206 can include semiconductor devices, such as byte select transistors, that may be connected to the regions 202, 204. In some examples, the byte separation region 206 can be used to accommodate memory components between adjacent memory bytes, such as a Cg-line and a byte select transistor. Some example semiconductor devices that can be put in the byte separation region 206 are described with reference to FIGS. 3A-3C.

The memory byte region 202 includes active bits 208a, 208b, 208c. For example, each of the active bits 208a-c may correspond to one of the memory cell 104 of FIG. 1. For example, the active bits 208a-c can corresponds to bits 5-7, respectively, in an 8-bit memory block. In this example, the memory cell region 202 includes a dummy bit 210 adjacent to the byte separation region 206. In some implementations, the dummy bit 210 may be a dummy semiconductor device without electrical functions for storing data. Similarly, the memory cell region 204 includes an active bit 212 and a dummy bit 214. For example, the active bit 212 may be the bit 0 of a memory block adjacent to the memory block represented by the memory cell region 202.

As shown, the memory structure 200 includes shallow trench isolation (STI) regions 216a-g. For example, the shallow trench isolation regions 216a-g are filled with STI materials, such as silicon dioxide or other dielectric materials. In this example, the STI regions 216a-g are used to provide electrical isolations against, for example, voltages and electrical current leakage between adjacent semiconductor device components (e.g., the active bits 208a-c).

In some implementations, shapes of the STI regions 216a-g are pattern dependent. A slope of a STI region depends on the density of bits near the STI region. In this example, two slopes 218a, 218b are shown for comparison. The slope 218a is a slope between bits that are further away from each other. In this example, the slope 218a is the slope along the surface between the STI region 216e and the dummy bit 214.

The slope 218b is a slope between bits that are closer to each other. In this example, the slope 218b is a slope between the STI region 216f and the active bit 212. Additionally, the slopes between the active bit 208a and the STI region 216a, the active bit 208a and the STI region 216b, the active bit 208b and the STI region 216c, and/or the active bit 212 and the STI region 216g can be substantially equal to the slope 218b.

In one example, the density of the bits around the STI region 216e is lower. For example, the byte separation region 206 is wider than separation regions between two active bits because the byte separation region 206 is used to separate adjacent memory blocks. Thus, the slope 218b is steeper than the slope 218a.

In various examples, the differences in the slopes 218a and 218b can create a process variation in the memory structure 200. Using the dummy bits 210, 214, the memory structure 200 can reduce the process variation by maintaining a substantially same density for the active memory bits 208a-c, 212 at the edge of the memory regions 202, 204. For example, by implementing the dummy bit 210, the memory structure 200 can maintain a same degree of isolation for the active bits 208b and 208c. As shown in the depicted example, a slope between the active bit 208c and the STI region 214c is substantially the same as the slope between the active bit 208b and the STI region 214c. In one implementation, useful features (e.g., a contact region of the memory structure 200, an integrated circuit resistor or capacitor, a wire, a via contact element) are constructed over the dummy bits 210, 214 to reduce the area of the byte separation region 206. Accordingly, functional use of the active area on which the dummy bit is disposed can offset the increase in area of memory structure 200 caused by adding dummy bits 210, 214. An example of such structure is described below.

FIGS. 3A-3C show multiple views of an example memory structure 300 having a contact region constructed to substantially overlay on a dummy cell. In one example, the memory structure 300 may be a part of a memory block 102 shown in FIG. 1. In another example, the memory structure 300 can be used in the memory structure 200 of FIG. 2 to reduce the increased area for including the dummy bits 210, 214.

As shown in FIG. 3A, the memory structure 300 is a memory block at row m and column k of a memory circuit (e.g., the memory circuit 100). In some implementations, other memory blocks in the memory circuit may be mirror images of the memory block depicted in FIG. 3A. As shown, an x symmetry axis and an y symmetry axis are included as mirror lines for the memory structure 300. In one example, an area 310 includes structures symmetric to the memory structure 300 along the x symmetry axis. In another example, an area 320 includes structures symmetric to the memory structure 300 along the y symmetry axis. In another example, an area 330 includes structures symmetric to the area 310 and the area 320 along the y symmetry axis and the x symmetry axis, respectively.

The memory structure 300 includes a memory cell region 342 and a byte separation region 344. For example, the memory cell region 342 and the byte separation region 344 can be a structure representing a memory block in a memory circuit. The memory cell region 342 includes an active region 346 and a dummy cell 348. Note that, for simplicity, there is only one active bit 346 shown in the memory cell region 342. However, for a byte-addressable memory, there are actually eight active bits in the memory cell region 342. In some examples, there may be seven more bits in an extended region (not shown) to the left of the active bit shown in FIG. 3A.

In some implementations, the memory structure 300 can also be used in a memory having a memory block size other than eight bits. For example, the memory structure 300 can be used in memory that has memory blocks of 4 bits, 16 bits, 32 bits, or 64 bits.

The active region 346 is connected to a bit line contact 350. For example, the bit line contact 350 can be connected to a bit line associated with the active bit. In some examples, because of the y symmetry, the bit line contact 350 can be common to another active bit in the area 320. For example, if the active bit shown in the active region 342 is bit 7 of the memory byte, the bit line contact 350 may also be connected to bit 7 of the memory block in the area 320. In this example, the dummy cell 348 is disconnected at a region 351 where bit line contacts are made at active bits. The dummy bit 348 is isolated from other dummy bits and has no electrical functions. In some implementations, the region 351 may be filled with STI materials. In other implementations, the dummy cell 348 can be disconnected or otherwise isolated at other parts of the region 348. By including the dummy cell 348, the memory structure 300 can provide a substantially uniform slope at the STI regions 362 between each individual bit in the active region 346.

The byte separation region 344 includes a metal conductor 352 and a byte select transistor 354. In some examples, the metal conductor 352 can transmit column select voltage (e.g., the Cg-line voltage of FIG. 1) that selects a column of the memory array. In this example, a source terminal of the byte select transistor 354 receives the column select voltage at a contact 356. The byte select transistor 354 also receives a row select voltage transmitted by a select gate 358. In some implementations, the select gate 358 spans substantially an entire row of a memory array. As shown, the select gate 358 spans row m of the memory array. For example, control gates of bit select transistors and byte select transistors in row m are commonly connected to the select gate 358.

Voltage can be applied to the byte select transistor 354 to enable the memory block in the memory cell region 342. In this example, the applied voltage is transmitted to the memory cell region 342 via a metal strap 364. The metal strap 364 is an L-shaped metal that is connected to the byte select transistor 354 in one end through a contact 366. At the other end, the metal strap 364 is connected to a control gate 368 via two contacts 370a, 370b. Depending on various designs, other shapes and sizes of the metal strap 364 can also be used. For example, the metal strap 364 can be a straight bar having a contact on each end, connecting the byte select transistor 354 to the memory cell region 342.

FIG. 3B shows an example cross-section of the memory structure 300 along the line 2-2 in FIG. 3A. In one implementation, the select gate 358 can be polysilicon constructed on top of a layer of gate oxide 360. As shown, the memory structure 300 also includes STI regions 362. For example, the STI regions 362 may be filled with isolation materials, such as silicon oxide (e.g., silicon dioxide, tetraethyl orthosilicate (TEOS).). In this example, the select gate 358 is constructed on top of the gate oxide 360 and spans across the memory cell region 342 and the byte separation region 344.

FIG. 3C shows an example cross-section view of the memory structure 300 along the line 1-1 in FIG. 3A. In some examples, the cross-section 1-1 may represent a word line structure that connects the metal connector 352 to each of the memory bytes in a memory array. As shown, the metal strap 364 is built on top of a field oxide 372. The metal trap 364 is coupled to the control gate 368 via the contact 370a at the dummy cell 348.

In this example, the metal strap 364 is also connected to a word line poly 374 via the contact 366. For example, the word line poly 374 may be coupled to a drain terminal of the byte select transistor 354 to transmit a word enable signal from the byte select transistor 354 to the memory block.

In some implementations, a size of the dummy cell 348 is approximately equal to the active region 346. As shown, each of the regions 346 and 348 includes a floating gate 376. In some implementations, the floating gate 376 at the dummy cell 348 can be optional.

As shown in FIGS. 3A and 3C, the memory structure 300 includes a contact region 380 “folded” on top of the dummy cell 348. Referring to FIG. 3A, the contact region 380 includes the contacts 370a-b for connecting the memory cell region 342 to the byte select transistor 354. In some examples, an area of the byte separation region 344 can be reduced by constructing the contact region 380 on top of the dummy cell 348. Accordingly, the overall area of the memory structure 300 having eight active memory cells with a dummy cell is substantially equal to a memory structure having eight active memory cells without a dummy cell.

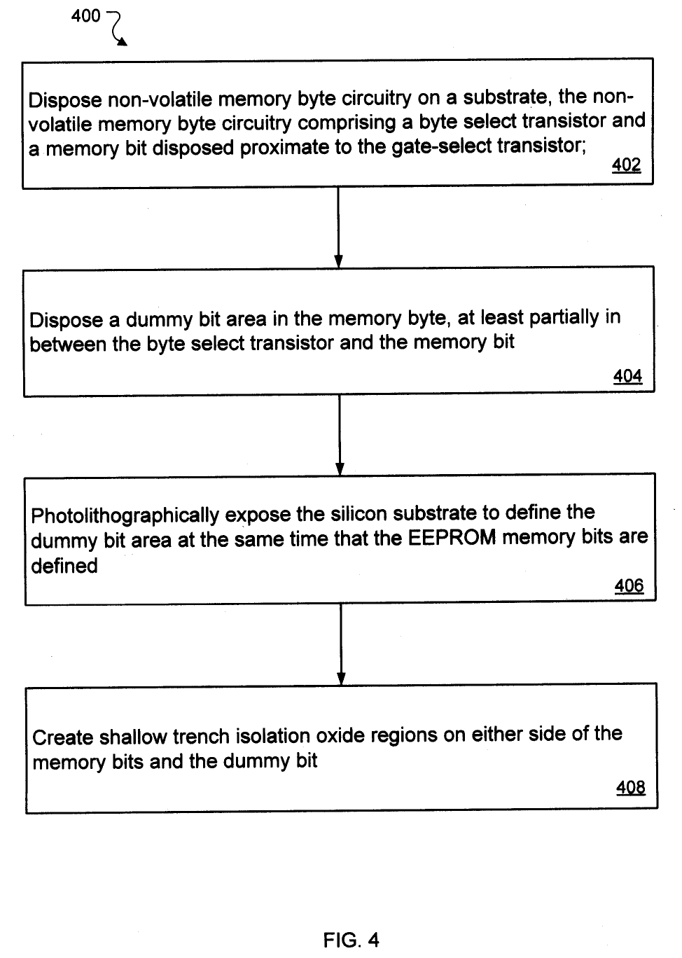

FIG. 4 is a flowchart illustrating an example method 400 for reducing the effect of process variations in a non-volatile memory.

The method 400 begins with disposing non-volatile memory byte circuitry on a substrate, the non-volatile memory byte circuitry comprising a byte select transistor and a memory bit disposed proximate to the gate-select transistor (402). For example, the memory structure 300 can include the byte select transistor 364 and the active region 346 on a substrate.

Next, the method 400 includes disposing a dummy bit area in the memory byte at least partially in between the byte select transistor and the memory bit (404). For example, the memory structure 300 includes the dummy region 348 between the active region 346 and the byte select transistor 364. In some implementations, the dummy bit area and the memory bit are substantially identical in size and/or orientation. For example, the dummy region 348 and each of the memory cell in the active region 346 can be substantially identical in size and orientation. In some implementations, the memory bit and the dummy area are spaced apart by a width substantially identical to the width of a separation among the memory bits. In an example shown in FIG. 2, the separation between the dummy bit 210 and the active bit 208c are substantially identical to the separations between the active bits 208a-c.

The method 400 includes photolithographically exposing the silicon substrate to define the dummy bit area at the same time that the EEPROM memory bits are defined (406).

After exposing the silicon substrate, the method 400 includes creating shallow trench isolation oxide regions on either side of the memory bits and the dummy bit (408). In one implementation, the dummy bit area isolates the byte select transistor from the memory bit disposed closest to the byte select transistor and precludes the need to use a wide STI oxide for isolation. In some examples, the process variation associated with the wide STI oxide can be avoided using the dummy bit.

A number of implementations of the invention have been described. Nevertheless, it will be understood that various modifications may be made without departing from the spirit and scope of the invention. Accordingly, other implementations are within the scope of the following claims.

What is claimed is:

1. A byte-addressable non-volatile memory, comprising:
a substrate;
non-volatile memory formed on the substrate, the non-volatile memory organized into memory bytes; and
a dummy bit area included in the memory bytes, the dummy bit area disposed between a byte select transistor and a non-volatile memory bit disposed proximate to the byte select transistor,
wherein the dummy bit area is electrically isolated from the memory bit and the byte select transistor.

2. The byte-addressable non-volatile memory of claim 1, wherein the non-volatile memory comprises an Electrically Erasable and Programmable Memory (EEPROM).

3. The byte-addressable non-volatile memory of claim 1, wherein N vertically directed columns of memory bytes comprise N/2 pairs of memory bytes that are substantially symmetric about a Y-axis and are substantial the same as each other, wherein the Y-axis is substantially coplanar with the surface of the substrate.

4. The byte-addressable EEPROM integrated circuit of claim 1, wherein M horizontally directed rows of memory bytes comprise M/2 pairs of memory bytes that are substantially symmetric about an X-axis and are mirror-images of each other, wherein the X-axis is substantially coplanar with the surface of the substrate.

5. The byte-addressable non-volatile memory of claim 1, wherein the dummy bit is disposed over an active area.

6. The byte-addressable non-volatile memory of claim 5, wherein the dummy bit area is operable to provide substantially the same active area width as the memory bit.

7. The byte-addressable non-volatile memory of claim 6, wherein a contact pad is disposed on the dummy bit area.

8. The byte-addressable non-volatile memory of claim 7, wherein the contact pad is a contact pad for connecting a non-volatile memory word line to a non-volatile memory control-gate.

9. A method of reducing the effect of process variations in a non-volatile memory, comprising:
disposing non-volatile memory byte circuitry on a substrate, the non-volatile memory byte circuitry comprising a byte select transistor and a memory bit disposed proximate to the gate-select transistor;
disposing a dummy bit area in the memory byte, at least partially in between the byte select transistor and the memory bit,
wherein the dummy bit area is substantially identical in size or orientation to the memory bit of the memory byte, and spaced apart from the memory bit by a width substantially identical to the width of a separation between the memory bit and a second memory bit disposed proximate to the memory bit.

10. The method of claim 9, further comprising:
photolithographically exposing the silicon substrate to define the dummy bit area at the same time that the EEPROM memory bits are defined; and
creating shallow trench isolation oxide regions on either side of the memory bits and the dummy bit;
wherein the dummy bit area isolates the byte select transistor from the memory bit disposed proximate to the byte select transistor.

11. The method of claim 10, further comprising using the dummy bit area to provide an additional function separate from an electrical isolation function.

12. The method of claim 10, further comprising disposing a contact pad for connecting a non-volatile memory word line to a non-volatile memory control-gate on the dummy bit area.

13. A byte-addressable non-volatile memory comprising:
a substrate;
non-volatile memory means formed on the substrate, the non-volatile memory means organized into memory bytes; and
isolation means included in the memory bytes, the isolation means disposed between a byte select transistor and a non-volatile memory bit disposed proximate to the byte select transistor,
wherein the isolation means isolates the memory bit electrically from the byte select transistor.

14. The byte-addressable non-volatile memory of claim 13, wherein the isolation means is used to provide an additional function separate from the electrical isolation function.

15. The byte-addressable non-volatile memory of claim 13, wherein a contact pad for connecting an EEPROM word line to an EEPROM byte select is disposed on the dummy bit area.
